(19) United States
(12) Patent Application Publication
(10) Pub. No.: US 2004/0189292 A1
(43) Pub. Date: Sep. 30, 2004

(54) Mechanism for and method of biasing magnetic sensor

(76) Inventor: David R. Kautz, Lenexa, KS (US)

Correspondence Address: THOMAS B. LUEBBERING, HOVEY WILLIAMS LLP, Suite 400, 2405 Grand, Kansas City, MI, 64108, US

(21) Appl. No.: 10/394,330

(22) Filed: Mar. 25, 2003

(51) Int. Cl. G01R 33/02; G01R 35/00

(52) U.S. Cl. 324/244; 324/202; 324/246

(57) ABSTRACT

A magnetic sensor package having a biasing mechanism involving a coil-generated, resistor-controlled magnetic field for providing a desired biasing effect. In a preferred illustrated embodiment, the package broadly comprises a substrate; a magnetic sensor element; a biasing mechanism, including a coil and a first resistance element; an amplification mechanism; a filter capacitor element; and an encapsulant. The sensor is positioned within the coil. A current applied to the coil produces a biasing magnetic field. The biasing magnetic field is controlled by selecting a resistance value for the first resistance element which achieves the desired biasing effect. The first resistance element preferably includes a plurality of selectable resistors, the selection of one or more of which sets the resistance value.

### FEDERALLY SPONSORED RESEARCH OR DEVELOPMENT PROGRAM

The present invention was developed with support from the U.S. government under Contract No. DE-AC04-01AL66850 with the U.S. Department of Energy. Accordingly, the U.S. government has certain rights in the present invention.

### BACKGROUND OF THE INVENTION

1. Field of the Invention

The present invention relates broadly to the field of magnetic sensors and to techniques for biasing magnetic sensors. More particularly, the present invention concerns a magnetic sensor package comprising a magnetic sensor element biased by a magnetic field produced by a current carried on a coil of electrically conductive wire and controlled by a selected one or more resistors from a plurality of selectable resistors to achieve a desired biasing effect, wherein at least the magnetic sensor element and the coil are protectively housed within an encapsulant.

2. Description of the Prior Art

Magnetic sensors are used in a variety of applications, including, for example, current sensing, linear or rotary motion detection, wheel speed sensing, and media (e.g., inks, currency) detection. It is often necessary or desirable to bias the magnetic sensor to, for example, provide a reference or set a condition of operation. A well-known prior art technique for biasing the magnetic sensor involves repositioning a permanent magnet in close proximity to the magnetic sensor until the desired degree of bias or biasing effect is achieved, whereafter the permanent magnet is permanently affixed in the corresponding position.

Unfortunately, this and other prior art biasing techniques suffer from a number of problems and disadvantages, including, for example, that the final position of the permanent magnet is directly related to and dictated by the required bias. This can be particularly problematic when the necessary position of the permanent magnet is already occupied by another component, or when the necessary position is beyond the bounds of the sensor's housing or allotted space.

Furthermore, because the permanent magnet must be physically repositioned, initial biasing can only be performed by a human or by a robot capable of moving the permanent magnet with the necessary degree of care and precision. This can be undesirably inefficient and expensive.

Additionally, because the permanent magnet must be accessible in order to be repositioned, both the magnetic sensor and the permanent magnet cannot be provided in a single sealed housing. As a result, the components of the magnetic sensor are exposed to a potentially damaging ambient environment and hazards of use, including dust and moisture, that can adversely affect performance.

Due to the above-identified and other problems and disadvantages in the art, a need exists for an improved mechanism for or method of biasing a magnetic sensor.

### SUMMARY OF THE INVENTION

The present invention overcomes the above-described and other problems and disadvantages in the prior art with a magnetic sensor package having a biasing mechanism involving a coil-generated, resistor-controlled magnetic field for providing a desired biasing effect. In a preferred illustrated embodiment, the package broadly comprises a substrate; a magnetic sensor element; a biasing mechanism; an amplification mechanism; a filter capacitor element; and an encapsulant.

The substrate is substantially conventional, and presents a first side and a second side. Where board space is a consideration, certain components of the package can be located on the first side and other components can be located on the second side, thereby allowing for a minimized footprint. Electrically conductive circuit traces are applied to the substrate to electrically interconnect the other components of the package.

The magnetic sensor element is substantially conventional and is operable to sense magnetic phenomena. The biasing mechanism is adapted to bias the sensor by a necessary or desirable degree. The biasing mechanism includes a coil and a first resistance element. The coil is a coated air coil of electrically conductive wire, and is adapted to produce a biasing magnetic field when a current is carried on the coil. The sensor is positioned substantially within the coil and therefore substantially within the biasing magnetic field. The first resistance element cooperates with the coil to achieve the desired biasing effect or otherwise set a desired characteristic of the biasing magnetic field. The first resistance element is preferably embodied in a surface-mount chip of selectable resistors wherein selection of one or more of the selectable resistors sets a resistance value and thereby controls the biasing effect.

The amplification mechanism includes both an amplifier element and a second resistance element. The amplifier operates to amplify an output signal of the sensor by a necessary or desirable degree or gain factor. The second resistance element cooperates with the amplifier to set the gain factor. The second resistance element may be embodied in and operate similar to the surface-mount chip of selectable resistors described above.

The filter capacitor element is adapted to filter input voltage lines to both the sensor and the amplification mechanism. The encapsulant cooperates with the substrate to protectively house or enclose at least the sensor and the coil.

Thus, it will be appreciated that the present invention provides a number of substantial advantages over the prior art, including, for example, that positioning of the bias-controlling first resistance element is completely independent of the biasing effect, meaning it can be positioned anywhere convenient or otherwise desirable. By contrast, in prior art biasing, the position of the permanent magnet used to control the biasing effect is directly related to and dictated by the biasing effect.

Furthermore, because the first resistance element need not be physically repositioned to achieve the desired biasing effect, the present invention is more agreeable to being computer-controlled or otherwise automated whereby, for example, a computer selects one or more of the first resistors from the plurality of selectable resistors to achieve the desired biasing effect.

Additionally, again because no repositioning of components is involved in biasing, the encapsulant can permanently cover at least some of the package's components, including the sensor and the coil, to protect them from the potentially damaging ambient environment and hazards of use.

Additionally, where board space is a consideration, certain of the components can be grouped and placed on the first side of the substrate and others of the components can be placed on the second side of the substrate.

These and other important features of the present invention are more fully described in the section titled DETAILED DESCRIPTION OF A PREFERRED EMBODIMENT, below.

### BRIEF DESCRIPTION OF THE DRAWINGS

A preferred embodiment of the present invention is described in detail below with reference to the attached drawing figures, wherein:

FIG. 1 is a circuit schematic of a preferred embodiment of the magnetic sensor of the present invention;

FIG. 2 is a plan view of the magnetic sensor of FIG. 1;

FIG. 3 is a bottom view of the magnetic sensor of FIG. 1; and

FIG. 4 is an elevation view of the magnetic sensor of FIG. 1.

### DETAILED DESCRIPTION OF A PREFERRED EMBODIMENT

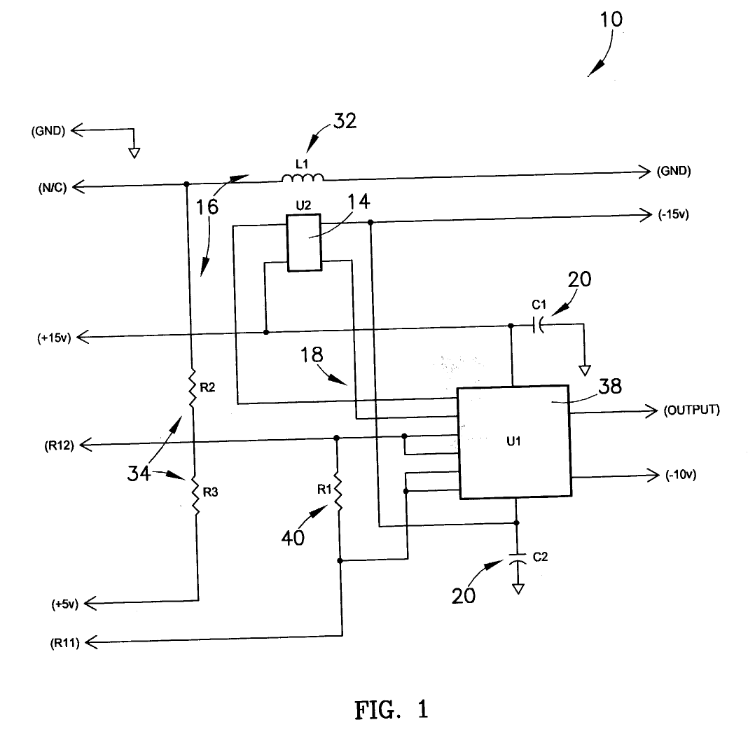

Referring to FIGS. 1-4, a magnetic sensor package 10 is shown constructed in accordance with a preferred embodiment of the present invention. The package 10 is biased by a coil-generated, resistor-controlled magnetic field, and is otherwise adapted to detect a magnetic phenomenon and to produce an amplified output signal corresponding thereto. In a preferred illustrated embodiment, the package 10 broadly comprises a substrate 12; a magnetic sensor element 14; a biasing mechanism 16; an amplification mechanism 18; a filter capacitor element 20; and an encapsulant 22.

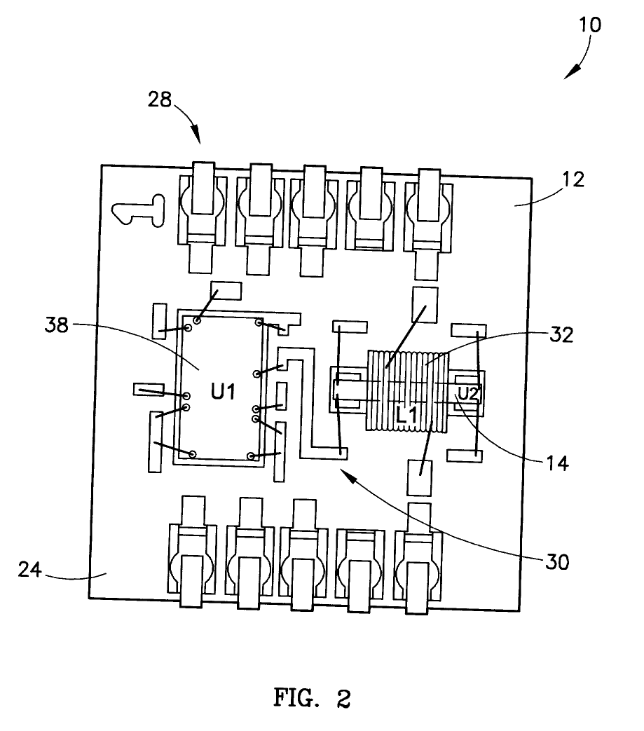

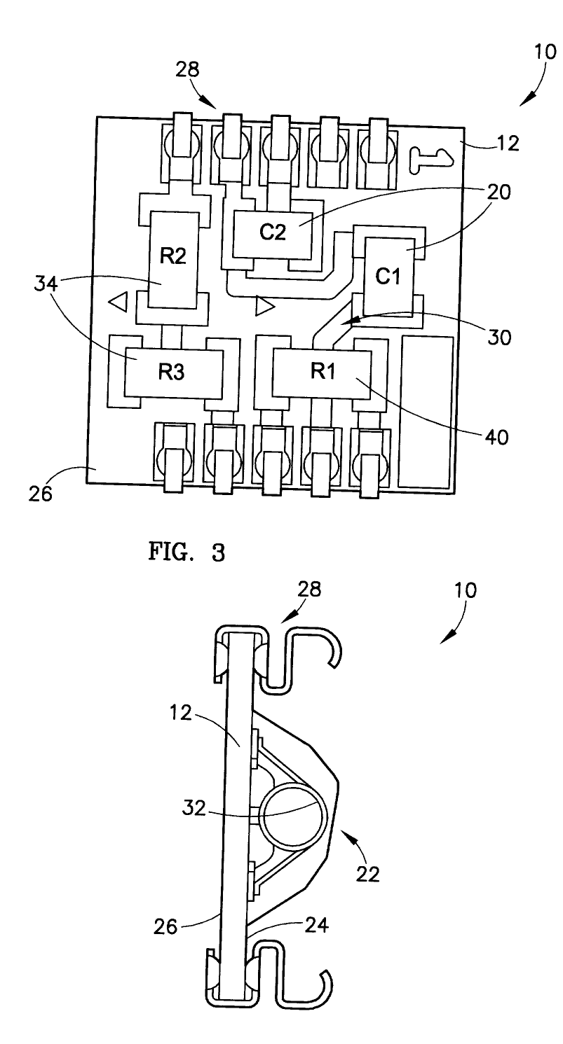

The substrate 12 is constructed from one or more commonly available materials, such as, for example, ceramic or printed circuit board (PCB) materials, and, in a substantially conventional manner, provides mounting and structural support for the other components of the package 10. As illustrated, the substrate 12 presents a first side 24 (see particularly FIG. 2) and a second side 26 (see particularly FIG. 3). To minimize the substrate's footprint, the magnetic sensor element 14, portions of the biasing mechanism 16, portions of the amplification mechanism 18, and the encapsulant 22 are mounted or otherwise located on the first side 24 of the substrate 12, while other portions of the biasing mechanism 16, other portions of the amplification mechanism 18, and the filter capacitor element 20 are mounted or otherwise located on the second side 26 of the substrate 12. The first and second sides 24,26 may be electrically interconnected using edge connectors 28 or vias or a combination thereof. The present invention is not, however, limited to this arrangement, and may instead be configured, for example, such that all of the package's components are mounted on the same side of the substrate 12. A network of electrically conductive circuit traces is applied to the substrate 12 to electrically interconnect the other components of the package 10.

The magnetic sensor element 14 is commonly available in chip form from a variety of suppliers, and, in a substantially conventional manner, senses a magnetic phenomenon. As mentioned, the sensor 14 is located on the first side of the substrate 12.

The biasing mechanism 18 is adapted to bias the sensor 14 by a necessary or desirable degree to, for example, provide a reference or set a condition of the sensor's operation. The biasing mechanism 18 includes a coil 32 and the first resistance element 34. The coil 32 is a coated air coil of electrically conductive wire, and is adapted to produce a biasing magnetic field when an electric current is carried on the coil 32. The sensor 14 is positioned substantially within the coil 32 and therefore substantially within the biasing magnetic field. As such, the coil 32 is also located on the first side of the substrate 12.

The first resistance element 34 is electrically associated with the coil 32 and cooperates therewith to achieve a desired biasing effect or otherwise set a desired characteristic of the biasing magnetic field. The first resistance element 34 may provide a substantially fixed resistance value, but preferably provides a substantially selectable or otherwise adjustable resistance value. As illustrated, for example, the first resistance element 34 is embodied in a plurality of selectable first resistors provided in the form of one or more commonly available surface-mount chips of selectable resistors. Selection of one or more of the plurality of selectable first resistors sets the resistance value and thereby controls the biasing effect of the biasing magnetic field. Alternatively, the first resistance element 34 may be embodied in a potentiometer which also provides a similarly selectable resistance value. The first resistance element 34 is located on the second side of the Substrate 12.

The amplification mechanism 16 includes both an amplifier element 38 and a second resistance element 40, both of which are also commonly available in surface-mount chip form from a variety of suppliers. The amplifier 38 operates, in a substantially conventional manner, to amplify an output signal of the sensor 14 by a necessary or desirable degree or gain factor. The amplifier 38 is located on the first side of the Substrate 12.

The second resistance element 40 is electrically associated with the amplifier element 38 and cooperates therewith to set the gain factor. The second resistance element 40 may provide a substantially fixed resistance value, but preferably provides a substantially selectable or otherwise adjustable resistance value. Similar to the first resistance element 34, the second resistance element 40 is illustrated as being embodied in a plurality of first resistors provided in the form of one or more commonly available surface-mount chips of selectable second resistors. Selection of one or more of the plurality of second resistors sets the resistance value and thereby determines the gain factor. The second resistance element 40 is located on the second side of the substrate 12.

The filter capacitor element 20 is a commonly available component, and is, in a substantially conventional manner, adapted to filter input voltage lines to both the sensor 14 and the amplification mechanism 16. As mentioned, the filter capacitor element 20 is located on the second side of the substrate 12.

The encapsulant 22 cooperates with the substrate 12 to protectively house or enclose the sensor 14 and the coil 32. The encapsulant 22 may be, for example, a commonly available epoxy or other “glob-top” material analogous to a potting compound, wherein the encapsulant 22 is “globbed” onto and over the coil 32. Thus covered, these components are effectively protected against potentially damaging ambient environment or hazards of use. Use of the glob-top material, which is non-removable, is possible because no repositioning of the sensor 14 or the coil 32 is performed during biasing. Alternatively, the encapsulant 22 could take the form of a ceramic cover which is either removably or non-removably secured over at least the sensor 14 and the coil 32.

In exemplary use and operation, a current is first applied to the coil 32 to produce the biasing magnetic field. Then, the resistance value of the first resistance element 34 is set, such as, for example, by selecting one or more resistors from a plurality of selectable resistors, to achieve the desired biasing effect from the biasing magnetic field. Thereafter, if not already done, the resistance value of the second resistance element 40 is set to achieve the desired gain factor. The setting of these resistance values through the selection of resistors may be done by a computer or other automated mechanism.

From the preceding description, it will be appreciated that the present invention provides a number of substantial advantages over the prior art, including, for example, that positioning of the bias-controlling first resistance element 34 is completely independent of the biasing effect, meaning it can be positioned anywhere convenient or otherwise desirable. By contrast, in prior art biasing, the position of the permanent magnet used to control the biasing effect was directly related to and dictated by the biasing effect.

Furthermore, because the first resistance element 34 need not be physically repositioned to achieve the desired biasing effect, the present invention is more agreeable to being computer-controlled or otherwise automated, whereby, for example, a computer selects one or more of the first resistors from the plurality of selectable resistors to achieve the desired biasing effect.

Additionally, again because no repositioning of components is involved in biasing, the encapsulant can be placed over at least some of the package's components, including the sensor 14 and the coil 32, to protect them from an ambient environment and hazards of use.

Additionally, where board space is a consideration, certain of the components can be grouped and placed on the first side 24 of the substrate 12 and others of the components can be placed on the second side 26 of the substrate 12.

Although the invention has been described with reference to the preferred embodiments illustrated in the attached drawings, it is noted that equivalents may be employed and substitutions made herein without departing from the scope of the invention as recited in the claims. It will be appreciated, for example, that, as mentioned, all of the components can be located on a same side of the substrate such that both sides of the substrate are not be utilized.

Having thus described the preferred embodiment of the invention, what is claimed as new and desired to be protected by Letters Patent includes the following:

1. A magnetic sensor comprising:
a sensor element adapted to detect a magnetic phenomena; and
a biasing mechanism adapted to bias the sensor element, the biasing mechanism including
a coil of electrically conductive wire substantially surrounding the sensor element, and
a first resistance element electrically cooperating with the coil such that when a current is carried on the coil a biasing magnetic field having a desired characteristic is produced and biases the sensor element located substantially within the coil.

2. The magnetic sensor as set forth in claim 1, wherein the first resistance element is a first surface mount resistor chip providing a plurality of selectable first resistors, with a selected one or more of the first resistors electrically cooperating with the coil to result in the biasing magnetic field having the desired characteristic.

3. The magnetic sensor as set forth in claim 1, further including an amplification mechanism adapted to amplify an output signal produced by the sensor element, the amplification mechanism including—
an amplifier element adapted to amplify the output signal by a desired gain factor; and
a second resistance element electrically cooperating with the amplifier element to set the desired gain factor.

4. The magnetic sensor as set forth in claim 3, wherein the second resistance element is a second surface mount resistor chip providing a plurality of selectable second resistors, with a selected one or more of the second resistors resulting in the desired gain factor.

5. The magnetic sensor as set forth in claim 1, further including a filter capacitor element adapted to filter an input voltage line to the sensor element.

6. The magnetic sensor as set forth in claim 1, further including an encapsulant adapted to substantially cover and protect the sensor element and the coil.

7. The magnetic sensor as set forth in claim 6, wherein the encapsulant is a non-magnetic material permanently applied over the sensor element and the coil to protect against exposure and mechanical shock.

8. A magnetic sensor package comprising:
a sensor element adapted to detect a magnetic phenomena;
a biasing mechanism adapted to bias the sensor element, the biasing mechanism including
a coil of electrically conductive wire substantially surrounding the sensor element, and
a plurality of selectable first resistors, with a selected one or more of the first resistors electrically cooperating with the coil such that when a current is carried on the coil a biasing magnetic field having a desired characteristic is produced and biases the sensor element located substantially within the coil;
an amplification mechanism adapted to amplify an output signal produced by the sensor element, the amplification mechanism including—
an amplifier element adapted to amplify the output signal by a desired gain factor, and
a second resistance element adapted to electrically cooperate with the amplifier element to set the desired gain factor; and
an encapsulant adapted to substantially cover and protect at least the sensor element and the coil.

9. The magnetic sensor as set forth in claim 8, wherein the second resistance element provides a plurality of selectable second resistors which are selectable to result in the desired gain factor.

10. The magnetic sensor as set forth in claim 8, wherein the encapsulant is a non-magnetic material permanently applied over the sensor element and the coil to protect against exposure and mechanical shock.

11. The magnetic sensor as set forth in claim 8, further including a filter capacitor element adapted to filter an input voltage line to the sensor element.

12. A magnetic sensor package comprising:
a sensor element adapted to detect a magnetic phenomena;
a biasing mechanism adapted to bias the sensor element, the biasing mechanism including—
a coil of electrically conductive wire substantially surrounding the sensor element, and
a plurality of selectable first resistors, with a selected one or more of the first resistors electrically cooperating with the coil such that when a current is carried on the coil a biasing magnetic field having a desired characteristic is produced and biases the sensor element located substantially within the coil;
an amplification mechanism adapted to amplify an output signal produced by the sensor element, the amplification mechanism including—
an amplifier element adapted to amplify the output signal by a desired gain factor, and
a second resistance element adapted to electrically cooperate with the amplifier element to set the desired gain factor;
an encapsulant adapted to substantially cover and protect at least the sensor element and the coil;
a filter capacitor element adapted to filter an input voltage line to the sensor element; and
a substrate having a first side and a second side, with the sensor element, the coil, the amplifier element, and the encapsulant being mounted to the first side, and the plurality of selectable first resistors, the second resistance element, and the filter capacitor being mounted to the second side.

13. A method of biasing a magnetic sensor, the method comprising the steps of:
(a) positioning a sensor element within a coil of electrically conducting wire, wherein the sensor element is adapted to detect a magnetic phenomena; and
(b) associating electrically a first resistance element with the coil, such that a current carried on the coil produces a biasing magnetic field having a desired characteristic that biases the sensor element.

14. The method as set forth in claim 13, wherein the first resistance element is a first surface mount resistor chip providing a plurality of selectable first resistors, and the method further including the step of (c) selecting one or more of the first resistors to result in the biasing magnetic field having the desired characteristic.

15. The method as set forth in claim 13, further including the step of (c) amplifying an output signal produced by the sensor element using an amplification mechanism including—
an amplifier element adapted to amplify the output signal by a desired gain factor; and
a second resistance element electrically cooperating with the amplifier element to set the desired gain factor.

16. The method as set forth in claim 15, wherein the second resistance element is a second surface mount resistor chip providing a plurality of selectable second resistors, and the method further including the step of (d) selecting one or more of the second resistors to result in the desired gain factor.

17. The method as set forth in claim 13, further including the step of (c) filtering with a filter capacitor element an input voltage line to the sensor element.

18. The method as set forth in claim 13, further including the step of (c) encapsulating at least the sensor element and the coil with an encapsulant to substantially cover and protect at least the sensor element and the coil.

19. A method of biasing a magnetic sensor, the method comprising the steps of:
(a) positioning a sensor element within a coil of electrically conducting wire, wherein the sensor element is adapted to detect a magnetic phenomena;
(b) associating electrically a plurality of selectable first resistors with the coil, such that a current carried on the coil produces a biasing magnetic field;
(c) selecting one or more of the first resistors to result in the biasing magnetic field having a desired characteristic for biasing the sensor element;
(d) amplifying an output signal produced by the sensor element using an amplification mechanism including—
an amplifier element adapted to amplify the output signal by a desired gain factor, and
a second resistance element electrically cooperating with the amplifier element to set the desired gain factor;
(e) filtering with a filter capacitor element the output signal produced by the sensor element; and
(f) encapsulating at least the sensor element and the coil with an encapsulant to substantially cover and protect at least the sensor element and the coil.

20. The method as set forth in claim 19, wherein the second resistance element is a second surface mount resistor chip providing a plurality of selectable second resistors, and the method further including the step of (g) selecting one or more of the second resistors to result in the desired gain factor.
